(19) United States
(12) Patent Application Publication
(10) Pub. No.: US 2023/0205095 A1
(43) Pub. Date: Jun. 29, 2023

(54) METHOD AND SYSTEM FOR DETERMINING ONE OR MORE DIMENSIONS OF ONE OR MORE STRUCTURES ON A SAMPLE SURFACE

(71) Applicant: TERANOVA B.V., Eindhoven (NL)

(72) Inventors: Mohammad RAMEZANI, Eindhoven (NL); Jaime GÓMEZ RIVAS, Eindhoven (NL)

(73) Assignee: TERANOVA B.V., Eindhoven (NL)

(21) Appl. No.: 17/996,625

(22) PCT Filed: Jan. 8, 2021
(86) PCT No.: PCT/EP2021/050297

§ 371 Date: Oct. 20, 2022

Related U.S. Application Data
(60) Provisional application No. 63/014,307, filed on Apr. 23, 2020.

(51) Int. Cl. G03F 7/20; G01B 11/02

(52) U.S. Cl. CPC G03F 7/70483; G01B 11/02

(57) ABSTRACT

A method for determining one or more dimensions of one or more structures is disclosed. The method comprises focusing illumination light on a focal plane of a lens system so that the lens system forms a collimated illumination light beam that is incident on the sample surface. The method also comprises, using said lens system or, respectively, a further lens system, collecting reflected or, respectively, transmitted illumination light reflected from or transmitted through the sample surface. Further, the method comprises capturing an image of said focal plane or, respectively, further focal plane, said image representing a distribution in said focal plane or further focal plane of radiant power of the reflected or transmitted illumination light. A further step of the method comprises, based on the captured image, determining the one or more dimensions of the structures on the sample surface.

### FIELD OF THE INVENTION

This disclosure relates to a method and system for determining one or more dimensions of one or more structures on a sample surface. In particular to such method and system wherein illumination light is focused on a focal plane of a lens system so that a collimated illumination light beam is incident on the sample surface and wherein an image of the focal plane is captured. This disclosure further relates to a computer-implemented for determining the one or more dimensions based on such captured image and on a computer program, data processing system and storage medium for such computer-implemented method.

### BACKGROUND

Fabrication of the periodic, quasi-periodic and aperiodic nanostructures using techniques such as UV lithography, electron-beam lithography, nanoimprint lithography (NIL) and roll-to-roll imprinting over a large area wafers is a critical step for production of many different optical devices and systems. Despite the versatility of these techniques, homogeneity of the fabricated nano/microstructures over the entire wafer can vary significantly. Hence, metrology and inspection techniques for quality control of fabricated structures are very important.

Examples of such inspection techniques are scanning electron microscopy (SEM) and atomic force microscopy (AFM). However, these techniques are suboptimal because of their low throughput, destructive nature and very limited field of view. Further, even though SEM and AFM yield high resolution images, their accuracy in terms of measuring actual dimensions of structures is limited.

Another inspection technique is scatterometry. Herein properties of scattered light, scattered from a sample, are measured. Two main scatterometry techniques exist: spectroscopic scatterometry and angle-resolved scatterometry. Spectroscopic scatterometry measures the properties of scattered light at a fixed angle as a function of wavelength, usually using a broadband light source such as xenon, deuterium, or halogen based light source such as a xenon arc lamp. The fixed angle can be normally incident or obliquely incident. Angle-resolved scatterometry measures the properties of scattered light at a fixed wavelength as a function of angle of incidence, usually using a laser as a single wavelength light source.

EP1628164 A2 describes an example of a scatterometry technique. In particular, EP1628164 A2 discloses an apparatus and method to determine a property of a substrate by measuring, in the pupil plane of a higher numerical aperture lens, an angle-resolved spectrum as a result of radiation being reflected off the substrate.

In the field of quality inspection of sample surfaces, naturally a high throughput is very important. This namely allows to inspect samples in-line, as a step during the production process. Hence, in light of the above, there is a need in the art for sample surface inspection techniques that allow to inspect relatively large sample areas per unit of time so that a high throughput can be achieved.

### SUMMARY

To that end, a method for determining one or more dimensions of one or more structures is disclosed. The method comprises focusing illumination light on a focal plane of a lens system so that the lens system forms a collimated illumination light beam that is incident on the sample surface. The method also comprises, using said lens system or, respectively, a further lens system, collecting reflected or, respectively, transmitted illumination light reflected from or transmitted through the sample surface. Further, the method comprises capturing an image of said focal plane or, respectively, of a further focal plane of said further lens system, said image representing a distribution in said focal plane or further focal plane of radiant power of the reflected or transmitted illumination light. A further step of the method comprises, based on the captured image, determining the one or more dimensions of the structures on the sample surface.

This method is advantageous in that it enables to investigate large areas of a sample in a relatively short time and enables a high quality inspection throughput. By focusing the illumination light at the focal plane of the lens system, which focal plane may also be referred to as the pupil plane or as the back-focal plane of the lens system, a collimated illumination light beam is formed that is incident on the sample surface under a particular orientation. The illumination is reflected back from the sample surface, optionally while being scattered and/or diffracted, and/or transmitted through the sample surface, optionally while being scattered and/or diffracted. At least part of the reflected or transmitted illumination light is incident on the lens system again or on the further lens system. As a result, a distribution of radiant power of reflected or transmitted illumination light in the focal plane or further focal plane arises. As used herein, radiant power may also be referred to as intensity. It is understood that this distribution indicates how much of the incident illumination light is reflected or transmitted in which directions. Typically, if the one or more structures on the sample surface possess some periodicity, the illumination light is mostly reflected or transmitted in a discrete number of directions, also referred to as diffraction orders. Then, the radiant power in the focal plane or further focal plane is concentrated at some discrete positions in the focal plane. These concentrations of radiant power then correspond to the diffraction orders mentioned above. Determining one or more dimensions of one or more structures based on the distribution of radiant power of reflected/transmitted light in the (further) focal plane does not necessarily require that the illumination light is focused at a single point on the sample. Dimensions can also be determined if the reflected or transmitted illumination light originates from a large illuminated area on the sample. The distribution of radiant power in the focal plane or further focal plane of reflected or transmitted illumination light is very sensitive to the physical arrangement of the one or more structures on the sample surface. Even if the illuminated area on the sample contains many structures, a deviation in the dimensions of only few, e.g. only one, of these structures would already leave its footprint in the distribution of radiant power of the reflected or transmitted illumination light in the focal plane or further focal plane. To add to this, using a well-defined angle of incidence simplifies significantly the understanding of the optical response of the sample under investigation. Hence, this method allows to determine, with great accuracy, one or more dimensions of one or more structures in a relatively large area on the sample.

Besides semiconductor industries, many other industries can benefit from this method. The methods described herein can be used as an intermediate tool to determine dimensions of for example patterned structures immediately after lithography and before entering further steps of production. This leads to significant cost/reduction and improvement of the production yield.

It should be appreciated that in the context of this disclosure a lens system that collects reflected light is often referred to as “lens system” and a lens system that collects transmitted light is often referred to as further lens system. However, “lens system” may also refer to both types of lens system, thus both to the type for collecting reflected light and the type for collecting transmitted light.

The one or more structures are for example one or more nanostructures and/or a thin film on the sample surface. Such thin film may be a polymer film, such as photoresist. Further, such thin film may have been spin-coated onto the sample surface.

Dimensions of the structures as used herein may be understood to indicate the physical size of the structures. Determining one or more dimensions of the structures may be performed by determining their height and/or length and/or width and/or depth. The one or more structures may be a grating. Examples of dimensions that can be determined of such gratings include the type of symmetry and orientation of the grating, the pitch of the grating, the height and/or length and/or width and/or depth and/or duty cycle of the structures forming a unit cell of the grating.

Additionally or alternatively, determining a dimension of the structures may be performed by determining that the structures have another dimension than some targeted or desired dimension. Such determination is by itself already a valuable determination, even if it remains unknown what the actual dimension of the structure is. For example, determining that the height of structure, e.g. the height (thickness) of a polymer thin film, is different from a targeted or desired height, should also be understood as a determination of the height of the structure. Such determination may be performed when the method is for example used as a quality inspection method. Then typically some of the investigated samples will have a structure having a dimension that lies outside of an acceptable range.

The illumination light may be coherent light, as for example described by Kumar et al. in Proc. of SPIE Vol. 8324, 83240Q” “Coherent Fourier Scatterometry (Tool for improved sensitivity in semiconductor metrology)”.

The illumination light may be polarized, e.g. TM (transverse magnetic) polarized or TE (transverse electric) polarized. Additionally or alternatively, the reflected or transmitted illumination light may be polarization filtered.

The lens system and/or further lens system may comprise a high NA (numerical aperture) objective. The lens system may comprise one or more lenses. In one embodiment, the reflected or transmitted light

Typically, the illumination light is scattered when it is reflected by and/or transmitted through the sample surface. In such case, the reflected or transmitted illumination light may also be referred to as scattered illumination light. However, it may also be that unscattered reflection of the illumination light occurs at the sample surface, which may be referred to as a specular or mirror-like reflection.

The captured image typically consists of a plurality of spatially arranged pixels, wherein each pixel corresponds to a spatial position of said focal plane or further focal plane. The pixels typically have respective pixel values. Each pixel value for example indicates a radiant power that is present at its associated position in the focal plane or further focal plane. It should be appreciated that radiant power of light indicates a radiant energy of the light emitted, reflected, transmitted or received, per unit time. Radiant power may be expressed as an amount of Watt. Radiant power may also be referred to simply as the intensity of light.

In an embodiment, a cross section of the collimated illumination light beam has a surface area of at least 5 micrometers, preferably at least 10 micrometers, more preferably at least 50 micrometers, most preferably at least 100 micrometers. The diameter may even be 300 micrometers.

Typically, varying the orientation of the collimated illumination light beam and/or its polarization does not influence the cross section of the collimated illumination light beam.

In an embodiment, the method comprises storing one or more reference images. Each of the one or more reference images is associated with a reference sample surface comprising one of more structures having known dimensions. Further, each reference image represents a reference distribution of radiant power of light in said focal plane or further focal plane. In this embodiment, determining the one or more dimensions of the one or more structures on the sample surface comprises comparing the captured image with the one or more reference images.

This embodiment provides a convenient manner for determining the one or more dimensions based on the captured image. It should be appreciated that the reference images may be images of the (further) focal plane that were captured while an illumination light beam described herein was actually incident on an actual reference samples having one or more structures of known dimensions on their surfaces. The references images may alternatively be simulated images that are obtainable by simulating the optical set-up and simulating what happens using standard electromagnetic methods, such as, transfer matrix, rigorous coupled wave analysis and/or finite element methods in the frequency or in the time domain, in particular simulating which distribution of radiant power of reflected or transmitted illumination light in the (further) focal plane arises, when a virtual reference sample is investigated. Such simulation is quite easily performed, not least because the sample only receives illumination light under a single orientation at any given time.

The simulations referred to herein may be standard simulations, such as Rigorous coupled wave analysis. In these simulations, the structure within one unit cell is defined (with periodic boundary conditions). This is called the simulation volume. Then, the simulation volume is simulated to be illuminated with the given polarization at a specific angle of incidence. The results of these simulations are the intensity of the diffracted orders. In this way, it is for example possible to scan the angle of incidence and simulate the intensity of the diffracted orders as a function of incidence angle.

Any reference sample surface referred to in this disclosure may be understood to comprise one or more structures of which the dimensions are known.

A comparison between a captured image and a reference image as referred to in this disclosure may comprise comparing the distribution of radiant power of the reflected or transmitted illumination light as represented by the captured image with a reference distribution of radiant power represented by the reference image. In this embodiment, the method may comprise determining a degree of similarity between the captured image and one of the reference images, and, based on this degree of similarity, determining that the dimensions of the one or more structures on the sample surface under investigation are equal to the dimensions of the one or more structures on the reference sample associated with said one reference image. Optionally, this embodiment comprises determining that the determined degree of similarity is higher than a threshold degree of similarity. The degree of similarity may also be referred to as the level of similarity.

In an embodiment, each of the one or more reference images has been obtained by performing a simulation of a collimated illumination light beam being incident on the reference sample surface associated with the reference images in question.

This embodiment is beneficial because it obviates the need to perform reference measurements on actual reference sample surfaces. Thus, a great variation of virtual reference sample surfaces can be generated and simulated easily to see which one yields a simulated reference image that is equal to the actually captured image. Additionally or alternatively, the reference sample surface may be generated using artificial intelligence techniques, such as machine learning algorithms.

Inverse modeling may for example be performed to find a (virtual) reference sample surface that—upon simulating that a collimated illumination beam is incident on it—yields a reference image equal to the captured image. Once such reference sample surface has been found, the sample surface under investigation may be determined to correspond to the found reference sample surface.

The simulated collimated illumination light beam preferably corresponds to the actual collimated illumination light beam incident on the sample surface.

In an embodiment, focusing illumination light on the focal plane of the lens system comprises focusing illumination light on the focal plane of the lens system so that the lens system forms a first collimated illumination light beam that is incident on the sample surface and that is reflected from or transmitted through the sample surface and comprises focusing illumination light on the focal plane of the lens system so that the lens system forms a second collimated illumination light beam that is incident on the sample surface and that is reflected from or transmitted through the sample surface.

This embodiment allows to vary the characteristics of the illumination light that is used for investigating the sample surface.

In such embodiment, even more than two collimated illumination light beams may be used, such as at least three, at least four, at least five, at least ten, at least twenty, at least forty, et cetera.

In an embodiment, the first collimated illumination light beam and second collimated illumination light beam are incident on the sample surface simultaneously.

The first and second collimated illumination light beams may differ in terms of their orientation with respect to the sample surface and/may differ in terms of their wavelength and/or in terms of their polarization. In a specific example, the first and second collimated illumination beam coincide in the sense that they have the same position, yet consist of light having different polarizations/color.

In an embodiment, the first collimated illumination light beam and second collimated illumination light beam are incident on the sample surface one after another.

As said, many more than two collimated illumination light beams may be used. These may all be incident on the sample surface simultaneously. Alternatively, these may all be incident of the sample surface one after another. In yet another example, some of these many illumination light beams are incident simultaneously, while others are incident one after another.

In an embodiment, focusing the illumination light on the focal plane of the lens system comprises focusing the illumination light at a first point in the focal plane, the first point having a first position relative to the lens system, so that the lens system forms the collimated illumination light beam that is incident on the sample surface while having a first orientation relative to the sample surface. In this embodiment, the method further comprises focusing the illumination light at a second point in the focal plane, the second point having a second position relative to the lens system different from the first position, so that the lens system forms a second collimated illumination light beam that is incident on the sample surface while having a second orientation relative to the sample surface that is different from the first orientation.

Varying the orientation with which the illumination light is incident on the sample surface enables accurate determination of the one or more dimensions of the one or more structures. After all, it may be that a defect on the sample influences the reflection or transmission considerably for one orientation, whereas the same defect may less significantly influence the reflection or transmission for another orientation of the illumination light beam relative to the sample.

Note that this embodiment enables to control, in a convenient manner, the orientation of the illumination light beam relative to the sample surface. Only the point at which the illumination light is focused in the focal plane needs to be varied in order to change the orientation of the collimated illumination light beam.

Of course, more than two orientations for the collimated illumination light beam may be used for investigation of the sample. Typically, an entire range of orientations is used as will be apparent from the figures.

The illumination light may be focused simultaneously on the first point in the focal plane and one the second point in the focal plane so that the first and second collimated illumination light beam are incident on the sample surface simultaneously. Alternatively, the illumination light is focused at the first point in said focal plane and thereafter at the second point so that the first and second collimated illumination light beam are incident on the sample surface on after another.

If the first and second light beam are incident simultaneously, then, preferably, the respective angles of incidence for the first and second collimated illumination light beam may differ by at least 5 degrees, preferably by at least 10 degrees. If the first and second light beam are incident simultaneously, then, preferably, substantially no light is incident on the sample surface having an angle of incidence between the first collimated illumination light beams' angle of incidence and the second collimated illumination light beams' angle of incidence.

In an embodiment, first illumination light is focused at the first point in said focal plane and then at the second point. In such embodiment focusing the illumination light at the first point and then at the second point comprises moving an illumination light source relative to said lens system and/or relative to an optical axis of the system.

In an embodiment, focusing the illumination light at the first point and at the second point comprises controlling a spatial light modulator to allow a first spatial portion of illumination light incident on the spatial light modulator to pass through and travel to the sample surface, and controlling the spatial light modulator to allow a second spatial portion of illumination light incident on the spatial light modulator to pass through and travel to the sample surface. On its way to the sample surface, the illumination light is focused on the focal plane of the lens system before it is incident on the sample surface.

The spatial light modulator may be controlled to allow the first and second spatial portion of the incident light beam to pass through. Alternatively, first one spatial portion may be allowed through and then another spatial portion.

In an embodiment, the method comprises controlling polarization of the illumination light such that the first collimated illumination light beam has a first polarization and the second collimated illumination light beam has a second polarization that is different from the first polarization.

This embodiment enables more accurate determination of the one or more dimensions of the one or more structures. A structural deviation on the sample surface may namely weakly influence the distribution of radiant power in the (further) focal plane for one type of polarization, whereas it may strongly influence the distribution of radiant power in the (further) focal plane for another type of polarization.

Also here, the first and second illumination light beam may be provided simultaneously or one after another.

It will be readily clear for the skilled person that during an investigation of a sample surface, both the orientation of the illumination light beam and the polarization may be varied. A first illumination light beam may have a first orientation and first polarization and a second illumination light beam may have a second orientation, different from the first orientation, and a second polarization, different from the first polarization.

In an embodiment, the first collimated illumination light beam comprises a first spectral power distribution, e.g. essentially consists of light having a first wavelength, and the second collimated illumination light beam comprises a second spectral power distribution different from the first spectral power distribution, e.g. essentially consists of light having a second wavelength different from the first wavelength.

This embodiment enables more accurate determination of the one or more dimensions of the one or more structures. A structural deviation on the sample surface may namely weakly influence the distribution of radiant power in the (further) focal plane for one illumination color, e.g. for red light, whereas it may strongly influence the distribution of radiant power in the (further) focal plane for another illumination color, e.g. for blue light.

If more than two collimated illumination light beams are used, then some of these may have the same spectral power distribution and/or polarization and/or orientation, whereas others may have differing spectral power distributions and/or polarizations and/or orientations.

In an embodiment, capturing an image of said focal plane or, respectively, of the further focal plane of the further lens system comprises (i) using said lens system or, respectively, further lens system, collecting first reflected or transmitted illumination light that is light from the first collimated illumination light beam reflected from or transmitted through the sample surface, and (ii) capturing a first image of said focal plane or, respectively, of said further focal plane, said first image representing a distribution in said focal plane or further focal plane of radiant power of the first reflected or transmitted illumination light, and (iii) using said lens system or, respectively, further lens system, collecting second reflected or transmitted illumination light that is light from the second collimated illumination light beam reflected from or transmitted through the sample surface, and (iv) capturing a second image of said focal plane or, respectively, of said further focal plane, said image representing a distribution in said focal plane or further focal plane of radiant power of the second reflected or transmitted illumination light. Such embodiment comprises, based on the first captured image and second captured image, determining the one or more dimensions of the one or more structures on the sample surface.

The first and second image may be captured simultaneously or one after another. It should be appreciated that the first and second image may be captured simultaneously by implementing appropriate filters in the system. To illustrate, if the first illumination light beam and second illumination light differ from each other in terms spectral power distribution, e.g. light color, then the first and second reflected/transmitted illumination light may be split based on their different spectral power distributions, e.g. using light color filters or splitters, known in the art and directed to different imaging systems. As another example, if the first and second illumination light beam differ in terms of polarization than appropriate polarization filters may be used to separate the first and second reflected/transmitted illumination light.

Of course, the first and second image are captured one after the other if the first and second illumination light beam are incident on the sample surface one after another.

If more than two illumination light beams are used, then preferably as many images are captured as illuminating light beams used.

In an embodiment wherein a first and second illumination light beam are used—irrespective of how they differ from each other—the method comprises storing one or more sets of reference images, each set comprising a first reference image associated with said first orientation and/or first polarization and/or first spectral power distribution of the illumination light beam and a second reference image associated with said second associated with said second orientation and/or second polarization and/or second spectral power distribution of the illumination light beam. Each reference image may represent a reference distribution of radiant power of light in said (further) focal plane. Each set is associated with a respective reference sample surface comprising one or more structures having known dimensions. In this embodiment, determining the one or more dimensions of the one or more structures on the sample surface comprises comparing the captured image with the first reference image in each of the one or more sets of reference images and comparing the second captured image with the second reference image in each of the one or more sets of reference images.

Each set of one or more reference images may be associated with a reference sample surface in that each of the one or more reference images represent a distribution of radiant power in the (further) focal plane that is caused by an illumination light beam, having various orientations and/or polarizations and/or spectral power distributions, that is reflected by and/or transmitted through, or simulated to be reflected by and/or simulated to be transmitted through, the associated reference sample surface.

It will be readily apparent for the skilled person that if more than two orientations or polarizations or spectral power distributions are used for investigating the sample, then each set of reference images preferably comprises as many reference images as used orientations/polarizations/spectral power distributions, namely at least one per orientation/polarization/spectral power distribution.

In an embodiment, the method comprises determining a region in the captured image, the region in the captured image comprising a plurality of pixels representing a radiant power in said focal plane or further focal plane of reflected or transmitted illumination light associated with a diffraction order. This embodiment also comprises determining the radiant power associated with said diffraction order based on said plurality of pixels in the region and comprises determining the one or more dimensions of the structures on the sample surface based on the determined radiant power associated with the diffraction order.

Determining a radiant power of a diffraction order based on a plurality of pixels may comprise summing respective pixel values of these plurality of pixels.

It should be appreciated that a reference image as referred to herein may simply indicate respective amounts of radiant power associated with respective diffraction orders, for example xx radiant power for 0^{th} order, yy radiant power for 1^{st} order, et cetera. Thus, a reference image as referred to in this disclosure does not necessarily indicate the spatial positions of the diffraction orders in the focal plane. Even if a reference image does not indicate the spatial positions of diffraction orders, then still it may be understood to represent a distribution of radiant power in the focal plane in that it represents how the radiant power is distributed across several diffraction orders in the (further) focal plane.

Thus, comparing a captured image and a reference image may be performed by comparing the radiant power of a diffraction order as indicated in the captured image with a radiant power of the same diffraction order as indicated in the reference image.

In an embodiment, the method comprises determining a first region in the captured image, the first region in the captured image comprising a plurality of pixels representing a first radiant power in said focal plane or further focal plane of reflected or transmitted illumination light associated with a diffraction order. This embodiment also comprises determining the first radiant power associated with said diffraction order based on said plurality of pixels in the first region. This embodiment further comprises determining a second region in the captured image, the second region in the captured image comprising a plurality of pixels representing a second radiant power in said focal plane or further focal plane of reflected or transmitted illumination light associated with a further diffraction order. Further, this embodiment comprises determining the second radiant power associated with the further diffraction order based on the plurality of pixels in the second region. This embodiment further comprises determining the one or more dimensions of the structures on the samples surface based on the determined first radiant power associated with the diffraction order and second radiant power associated with the further diffraction order.

In this embodiment, if reference images are obtained, then this reference image may indicate a first reference radiant power for said diffraction order and a second reference radiant power for said further diffraction order. Then, the step of determining the one or more dimensions may comprise comparing the first reference radiant power with the determined first radiant power and the second reference radiant power with the determined second radiant power.

Of course, the captured image may comprise more than two regions that are associated with even further diffraction orders.

In an embodiment, the method comprises determining a first region in the second captured image, the first region in the second captured image comprising a plurality of pixels representing a third radiant power in said focal plane or further focal plane of second reflected or transmitted illumination light associated with the diffraction order. This embodiment also comprises determining a second region in the second captured image, the second region in the second captured image comprising a plurality of pixels representing a fourth radiant power in said focal plane or further focal plane of second reflected or transmitted illumination light associated with the further diffraction order. In this embodiment further comprises determining said third radiant power based on said plurality of pixels of the first region in the second captured image, and determining the fourth radiant power based on said second plurality of pixels in the second region of the second captured image. The first reference image indicates a first reference radiant power for said diffraction order and a second reference radiant power for said further diffraction order. Also, the second reference image indicates a third reference radiant power for said diffraction order and a fourth reference radiant power for said further diffraction order. In this embodiment, the method comprises determining the one or more dimensions of the one or more structures on the sample surface comprises comparing said first radiant power with the first reference radiant power and the second radiant power with the second reference radiant power and the third radiant power with the third reference radiant power and the fourth radiant power with the fourth reference radiant power.

In an embodiment, the method comprises scanning the collimated illumination light, optionally the first and second collimated illumination light beam, over the sample surface. This embodiment enables to scan large areas of the sample.

It should be appreciated that this embodiment may be performed by performing a method for determining one or more dimensions described herein on a first area of a sample and then moving the sample with respect to the light source and then performing the method for determining one or more dimensions as described herein again on another area of the sample. Then, again, the sample may be moved with respect to the light source, et cetera, et cetera, until the desired area of the sample surface has been investigated.

Additionally or alternatively, this embodiment may be performed for example by keeping an illumination light beam, having a particular orientation and/or polarization and/or spectral power distribution, e.g. color, unchanged and moving the sample with respect to the light source in order to change which area on the sample surface receives the illumination light beam. Then, the orientation and/or polarization and/or spectral power distribution may be changed and then the sample may be moved again with respect to the light source n order to change which area on the sample surface receives the illumination light beam.

In an embodiment, focusing the illumination light on the focal plane of the lens system comprises simultaneously focusing the illumination light at a first point in the focal plane and at a second point in the focal plane, the first point having a first position relative to the lens system and the second point having a second position relative to the lens system different from the first position, so that the lens system forms the collimated illumination light beam that is incident on the sample surface while having a first orientation relative to the sample surface and simultaneously forms a second collimated illumination light beam that is incident on the sample surface while having a second orientation relative to the sample surface that is different from the first orientation. This embodiment optionally comprises controlling a spatial light modulator to simultaneously allow a first spatial portion and a second spatial portion of illumination light incident on the spatial light modulator to pass through and travel to the sample surface.

In an embodiment, focusing the illumination light on the focal plane of the lens system comprises focusing the illumination light at a first point in the focal plane and thereafter at a second point in the focal plane. The first point having a first position relative to the lens system and the second point having a second position relative to the lens system different from the first position, so that the lens system forms the collimated illumination light and the second collimated illumination light beam one after another. The collimated illumination light beam is incident on the sample surface while having a first orientation relative to the sample surface and the second collimated illumination light beam is incident on the sample surface while having a second orientation relative to the sample surface that is different from the first orientation. This embodiment optionally comprises controlling a spatial light modulator to allow a first spatial portion and thereafter a second spatial portion of illumination light incident on the spatial light modulator to pass through and travel to the sample surface.

It should be appreciated that the timing of the first and second light beam being incident on the sample is independent of how the first and second collimated illumination light beams differ from each other. They may differ in wavelength and/or orientation and/or polarization. If the first and second light beam have the same orientation yet differ in terms of their spectral power distribution and/or in terms of their polarization, then the first and second illumination light beams may be understood to be present in a single illumination light beam comprising both the first and second illumination light beam.

In an embodiment, the first and second collimated illumination light beam have the same orientation relative to the sample surface, and have a different spectral power distribution, and have the same polarization, and are incident on the sample surface simultaneously.

In an embodiment, the first and second collimated illumination light beam have the same orientation relative to the sample surface, and have a different spectral power distribution, and have the same polarization, and are incident on the sample surface one after another.

In an embodiment, the first and second collimated illumination light beam have a different orientation relative to the sample surface, and have the same spectral power distribution, and have the same polarization, and are incident on the sample surface simultaneously.

In an embodiment, the first and second collimated illumination light beam have a different orientation relative to the sample surface, and have the same spectral power distribution, and have the same polarization, and are incident on the sample surface one after another.

In an embodiment, the first and second collimated illumination light beam have a different orientation relative to the sample surface, and have a different spectral power distribution, and have the same polarization, and are incident on the sample surface simultaneously.

In an embodiment, the first and second collimated illumination light beam have a different orientation relative to the sample surface, and have a different spectral power distribution, and have the same polarization, and are incident on the sample surface one after another.

In an embodiment, the first and second collimated illumination light beam have the same orientation relative to the sample surface, and have the same spectral power distribution, and have a different polarization, and are incident on the sample surface simultaneously.

In an embodiment, the first and second collimated illumination light beam have the same orientation relative to the sample surface, and have the same spectral power distribution, and have a different polarization, and are incident on the sample surface one after another.

In an embodiment, the first and second collimated illumination light beam have the same orientation relative to the sample surface, and have a different spectral power distribution, and have a different polarization, and are incident on the sample surface simultaneously.

In an embodiment, the first and second collimated illumination light beam have the same orientation relative to the sample surface, and have a different spectral power distribution, and have a different polarization, and are incident on the sample surface one after another.

In an embodiment, the first and second collimated illumination light beam have a different orientation relative to the sample surface, and have the same spectral power distribution, and have a different polarization, and are incident on the sample surface simultaneously.

In an embodiment, the first and second collimated illumination light beam have a different orientation relative to the sample surface, and have the same spectral power distribution, and have a different polarization, and are incident on the sample surface one after another.

In an embodiment, the first and second collimated illumination light beam have a different orientation relative to the sample surface, and have a different spectral power distribution, and have a different polarization, and are incident on the sample surface simultaneously.

In an embodiment, the first and second collimated illumination light beam have a different orientation relative to the sample surface, and have a different spectral power distribution, and have a different polarization, and are incident on the sample surface one after another.

One aspect of this disclosure relates to a system for determining one or more dimensions of one or more structures, preferably nanostructures or a thin film, on a sample surface. The system comprises a lens system and a light focusing system that is configured to focus illumination light on a focal plane of the lens system so that the lens system forms a collimated illumination light beam that is incident on the sample surface. In the system (i) the lens system is configured to collect reflected illumination light reflected from through the sample surface and/or (ii) the system comprises a further lens system that is configured to collect transmitted illumination light transmitted through the sample surface. The system also comprises an imaging system that is configured to capture an image of said focal plane or of a further focal plane of the further lens system, said image representing a distribution in said focal plane or further focal plane of radiant power of the reflected or transmitted illumination light. Further, the system comprises a data processing system that is configured to, based on the captured image, determine the one or more dimensions of the structures on the sample surface.

One aspect of this disclosure relates to a computer-implemented method for determining one or more dimensions of one or more structures on a sample surface. This method comprises obtaining an image, the image representing a distribution in a focal plane or further focal plane of radiant power of reflected or transmitted illumination light. The image is obtainable by focusing illumination light on the focal plane of a lens system so that the lens system forms a collimated illumination light beam that is incident on the sample surface and, using said lens system or a further lens system, collecting reflected or transmitted illumination light reflected from or transmitted through the sample surface and capturing the image of the focal plane of further focal plane. The method further comprises storing one or more reference images, each of the one or more reference images being associated with a reference sample surface comprising one of more structures having known dimensions, and each reference image representing a reference distribution of radiant power of light in said focal plane or further focal plane. This method also comprises determining the one or more dimensions of the one or more structures on the sample surface comprises comparing the captured image with the one or more reference images.

Optionally, the computer-implemented method may comprise any step described herein that relates to determining the one or more dimensions of the one or more structures based on one or more captured images. For example, the computer-implemented may comprise storing one or more reference images described herein and/or comparing one or more reference images with one or more captured images as described herein and/or determining one or more regions in captured images having pixels representing a radiant power of one or more respective diffraction orders and/or determining a radiant power of a diffraction order based on a plurality of pixels.

Further, the computer-implemented method may comprise controlling a light source such that it generates illumination light, controlling a polarizing element for controlling a polarization of the illumination light, controlling a position of a light source relative to the lens system, controlling a spatial light modulator for subsequently allowing the first spatial portion and then a second spatial portion of incident illumination light to pass as described herein.

The data processing system of the system described herein may be configured to perform any step of such computer-implemented method.

One aspect of this disclosure relates to a data processing system comprising a processor that is configured to perform any of the computer-implemented methods disclosed herein.

One aspect of this disclosure relates to a data processing system that is configured to cause the system for determining one or more dimensions of one or more structures described herein to perform any of the methods described herein.

One aspect of this disclosure relates to a computer program comprising instructions which, when the program is executed by a data processing system, cause the data processing system to carry out the any of the computer-implemented methods described herein.

One aspect of this disclosure relates to a computer program comprising instructions which, when the program is executed by a data processing system, cause the system for determining one or more dimensions of one or more structures to carry out any of the methods described herein.

One aspect of this disclosure relates to a non-transitory computer-readable storage medium storing any of the computer programs referred to herein.

As will be appreciated by one skilled in the art, aspects of the present invention may be embodied as a system, a method or a computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Functions described in this disclosure may be implemented as an algorithm executed by a processor/microprocessor of a computer. Furthermore, aspects of the present invention may take the form of a computer program product embodied in one or more computer readable medium(s) having computer readable program code embodied, e.g., stored, thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples of a computer readable storage medium may include, but are not limited to, the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of the present invention, a computer readable storage medium may be any tangible medium that can contain, or store, a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber, cable, RF, etc., or any suitable combination of the foregoing. Computer program code for carrying out operations for aspects of the present invention may be written in any combination of one or more programming languages, including an object oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems), and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor, in particular a microprocessor or a central processing unit (CPU), of a general purpose computer, special purpose computer, or other programmable data processing apparatus to produce a machine, such that the instructions, which execute via the processor of the computer, other programmable data processing apparatus, or other devices create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

Moreover, a computer program for carrying out the methods described herein, as well as a non-transitory computer readable storage-medium storing the computer program are provided. A computer program may, for example, be downloaded (updated) to the existing data processing systems or be stored upon manufacturing of these systems.

Elements and aspects discussed for or in relation with a particular embodiment may be suitably combined with elements and aspects of other embodiments, unless explicitly stated otherwise. Embodiments of the present invention will be further illustrated with reference to the attached drawings, which schematically will show embodiments according to the invention. It will be understood that the present invention is not in any way restricted to these specific embodiments.

### BRIEF DESCRIPTION OF THE DRAWINGS

Aspects of the invention will be explained in greater detail by reference to exemplary embodiments shown in the drawings, in which:

FIG. 1A schematically illustrates a system according to an embodiment wherein reflected light is captured;

FIG. 1B schematically illustrates a system according to an embodiment wherein transmitted light is captured;

FIG. 2A is a flow chart illustrating a method according to an embodiment;

FIG. 2B illustrates an example of a sample surface according to an embodiment;

FIG. 3 illustrates a captured image according to an embodiment;

FIG. 4 schematically illustrates a system according to an embodiment wherein the light source is translated;

FIG. 5 schematically illustrates a system according to an embodiment comprising a spatial light modulator;

FIG. 6 illustrates the effect of displacing the illumination light with respect to the optical axis;

FIG. 7 illustrates a comparison between captured images and reference images according to an embodiment;

FIG. 8 illustrates a comparison between captured images and reference images according to an embodiment;

FIG. 9 illustrates a captured image according to an embodiment;

FIG. 10 illustrates an artifact that may arise in captured images according to an embodiment;

FIG. 11 illustrates removal of artifacts from captured images;

FIG. 12 illustrates the effect of artifact removal according to an embodiment;

FIG. 13 illustrates a data processing system according to an embodiment.

### DETAILED DESCRIPTION OF THE DRAWINGS

In the figures, identical reference numbers indicate identical or similar elements.

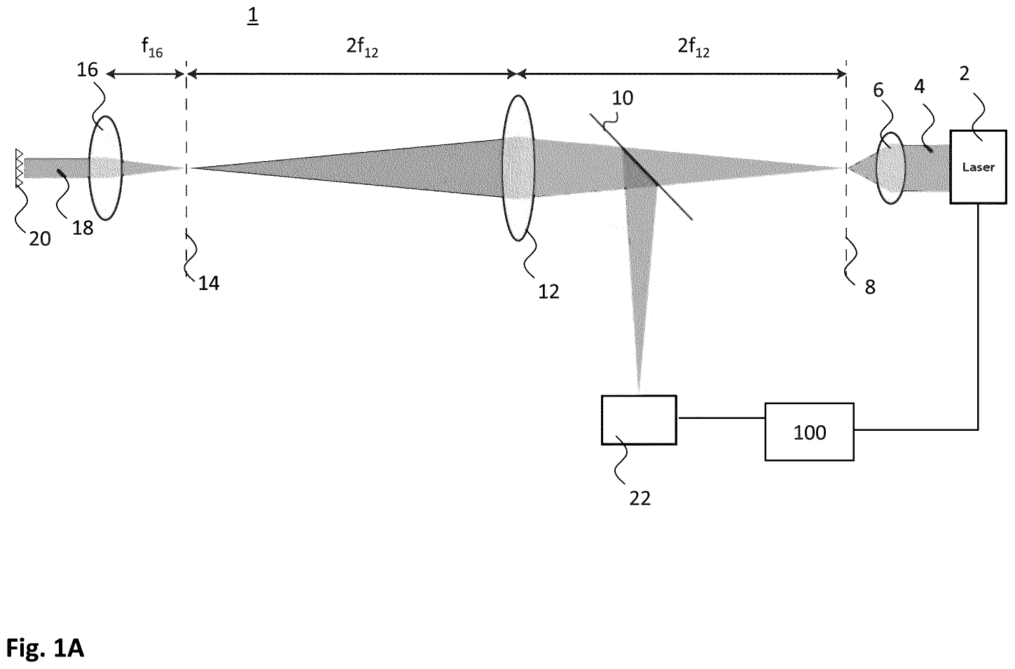

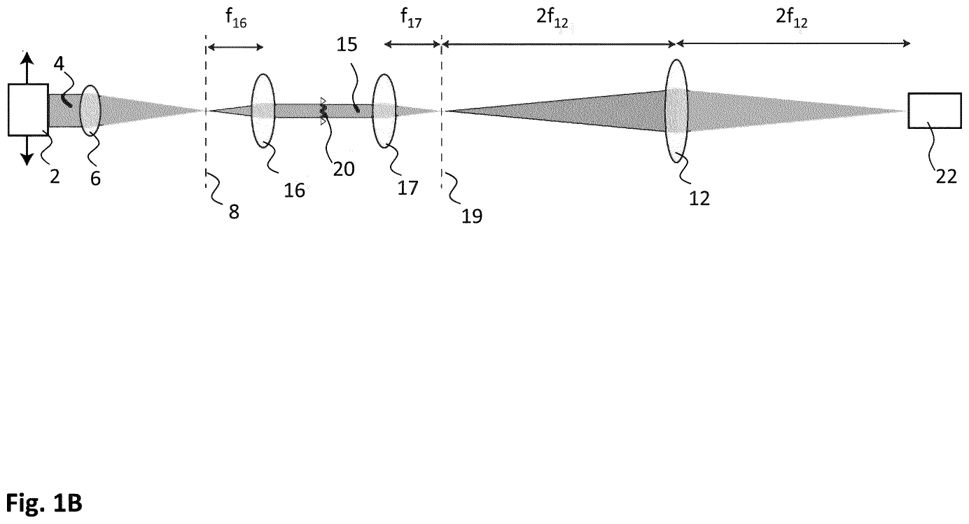

FIG. 1 schematically illustrates a system for determining one or more dimensions of one or more structures on a sample surface 20. A sample surface as referred to herein may be (but is not limited to) a surface of a silicon wafer, onto which semiconductor structures are fabricated. The one or more structures are for example nanostructures. Additionally or alternatively, the one or more structures may be a thin polymer layer, e.g. e polymer layer that has been spin coated onto the sample surface 20, such as on the silicon wafer.

The system 1 comprises a lens system 16, which may for example be a high NA objective and which may comprise a plurality of lenses. System 1 further comprises a light focusing system (comprising lenses 6 and 12) that is configured to focus illumination light on a focal plane 14, which may be referred to as the back focal plane, of the lens system 16 so that the lens system 16 forms a collimated illumination light beam 18 that is incident on the sample surface 20, under a well-defined angle of incidence. The collimated illumination light beam may be uniform in the sense that has the same radiant power across its cross section. The collimated illumination light beam 18 may have a cross section that has a surface area of at least five micrometers. The same or similar lens system 16 is configured to collect reflected or transmitted illumination light reflected from or transmitted through the sample surface 20. Hence, preferably, the lens system 16 is positioned as close to the sample surface 20 as possible in order to ensure a high NA of the system. In FIG. 1, the collimated illumination is realized using a laser light focused on a plane 8, wherein the distance between lens 12 and plane 8 is twice the focal lengths of lens 12. The focal spot is then imaged with 1:1 magnification ratio on plane 14, which is the focal plane of lens system 16. This spot is at the focal plane 14 of the lens 16 leads to an oblique angle of incidence on the sample proportional to the displacement from the optical axis.

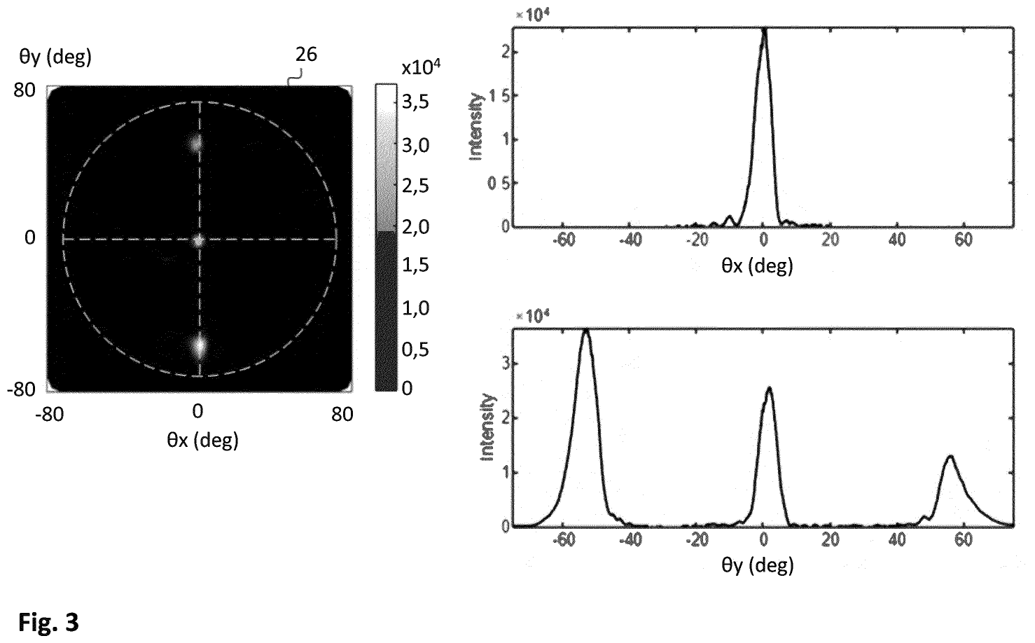

The system 1 further comprises an imaging system 22 that is configured to capture an image of said focal plane 14. The image represents a distribution in the focal plane of radiant power of the reflected or transmitted illumination light. An example of such captured image is shown in FIG. 3 and will be discussed in more detail below. The system 1 further comprises a data processing system 100 that is configured to, based on the captured image, determine the one or more dimensions of the structures on the sample surface 20.

In the embodiment of FIG. 1, the illumination light passes through beam splitter 10. Due to beam splitter 10, part of the reflected illumination light on its way back will be deflected towards imaging system 22. In the depicted embodiment, light focusing system 12 is not only configured to focus illumination light on the back focal plane 14 of the lens system 16, but also configured to focus reflected illumination light onto an imaging plane of imaging system 22.

Lens 6 may be an adjustable lens that allows to control whether the illumination light is focused on focal plane 14 or not. In the latter case, the illumination light 18 would be focused at the sample surface.

The systems and methods disclosed herein, for example one as shown in FIG. 1, enable to probe samples with a high spatial resolution and a well-defined angle of incidence. Using this technique one can simultaneously collect the orders of diffraction for a given incident angle using the same objective lens (reflection mode). Alternatively, the sample can also be illuminated from below, for example, and the diffraction orders can be collected from above to realize a system in transmission mode. The change in the angle of incidence in the collimated mode is realized by moving the focus of the laser spot on the back-focal plane 14. Translation with respect to the optical axis may be used to control the incident angle of the collimated light onto the sample.

In many cases one is interested in quantifying the response of the system under a well-defined angle of incidence. Therefore, the possibility of distinguishing the 20 response of the system based on the angle of incidence is relevant. Solar cells and photodetectors are examples of such structures that can benefit from well-defined illumination conditions. In addition, illumination of the sample with a well-defined angle of incidence significantly simplifies the analysis related to the diffraction orders. One of the challenges that this technique can overcome is providing visual inspection of the sample in addition to measuring the diffraction order. Generally, scatterometry is a non-imaging technique.

However, in this technology the 30 operator can simultaneously look at the sample using the microscope (visually) and measure the diffraction orders. This capability makes this technique more versatile to validate the properties of the samples. Significant advantages are provided, including but not limited to the following.

1) Easy illumination of a sample with a well-defined angle of incidence through a microscope objective within its numerical aperture.

2) Possibility to attain high-fluence non-focused illumination with a collimated beam under an objective due to the reduction of the beam diameter.

3) Analysis of optical response of the investigated individual nanostructure is easier because of the efficient collection of this signal by a microscope objective.

4) Possibility to investigate the directional emission of a nanostructure at the same time.

5) Possibility of measuring angle-dependence of light absorption in individual nanostructures without electrical contacts.

6) Possibility of large area scan.

7) Using measurement of diffraction orders (e.g., efficiency, width) for quality control of periodic, quasi periodic (and aperiodic) structures.

8) Sample independence.

An example of how these measurements are done is described below. The information is obtained in e.g. the back focal plane 14 of the objective lens and is imaged on e.g. a CCD camera 22 for further analysis. Several different criteria can be used to quantify the optical performance of the manufactured structures. The intensities of the obtained diffraction orders and their relative intensities with respect to the 0th order mode can quantify how efficient the grating is diffracting the light into the designated directions. In addition to the intensity, other metrics such as diffraction angles, full-width at half maximum are other metrics that can be used to estimate the performance of the sample or detect inhomogeneities in the sample. FIG. 3 represents the measurements of a blazed 1D grating where the −1 diffraction order is seen to be more efficient that the +1 diffraction order.

FIG. 1B schematically shows an embodiment in which a further lens system 17 collects transmitted light 15 that transmits through the sample surface 20. In such embodiment, an imaging system 22 is configured to capture an image of the further focal plane 19 of the further lens system 17. The captured thus represents a distribution in further focal plane 19 of radiant power of the transmitted illumination light 15. Based on such captured image, the one or dimensions of the structures on the sample surface can be determined using the methods described herein.

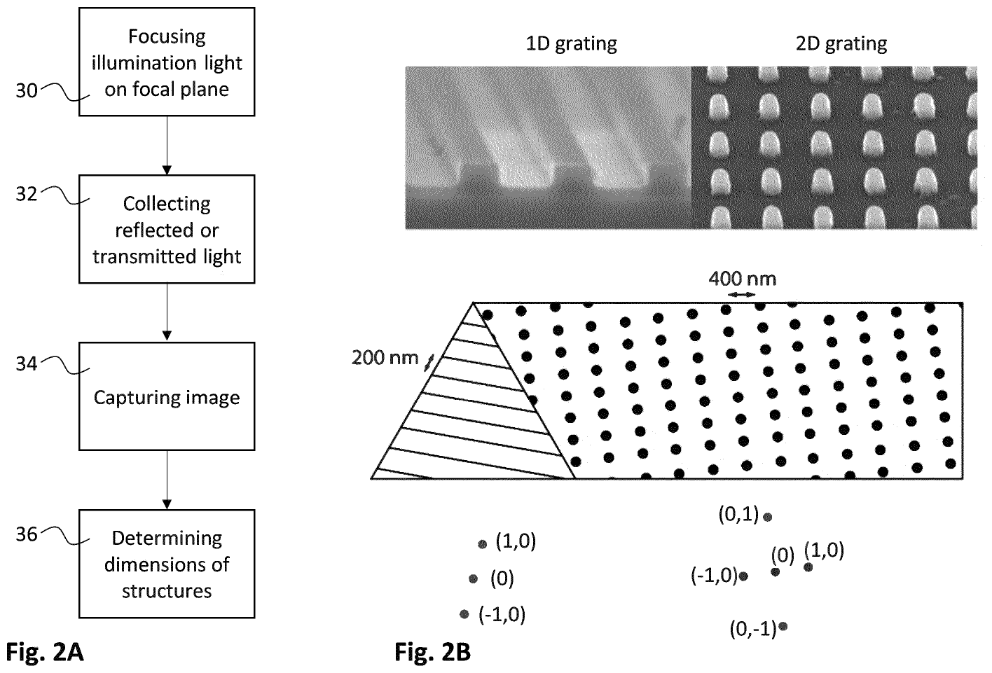

FIG. 2A is a flow chart illustrating a method according to an embodiment. Step 30 comprises focusing illumination light on a focal plane of a lens system so that the lens system forms a collimated illumination light beam that is incident on the sample surface. Step 32 comprises, using said lens system or a further lens system, collecting reflected or transmitted illumination light reflected from or transmitted through the sample surface. Step 34 comprises capturing an image of said (further) focal plane, said image representing a distribution in the (further) focal plane of radiant power of the reflected or transmitted illumination light. Step 36 comprises, based on the captured image, determining the one or more dimensions of the structures on the sample surface.

One aspect of this disclosure relates to a computer-implemented method for determining one or more dimensions of one or more structures based on captured images as described herein, and optionally based on reference images as described herein.

FIG. 2B illustrates the flexibility and versatility of the instrument toward the sample. In particular, the method described herein can be used to investigate samples having arbitrary geometries and design. FIG. 2B shows a cartoon of a generic design with on one side a triangle that contains 1D gratings along a vertical direction (such as shown in the top photograph) and on the other side a 2D rectangular lattice (such as shown in the top photograph). In order to measure the optical response of such a lattice, a measuring instrument needs to be flexible toward the symmetry of the sample and be able to detect all the diffraction orders simultaneously at different directions irrespective of the sample design. The diffraction orders of such a structure depending on design are shown at the bottom of FIG. 2B. The methods described herein allow the users to measure scattering/diffraction patterns regardless of the sample's symmetry (1D gratings or 2D square or hexagonal or etc.). This feature particularly becomes important when samples contain different lattices with different designs. In such case, conventional scanning techniques based on goniometers with detectors at different positions in space are not feasible anymore as one needs to adjust the detectors settings for different samples, leading to a time-consuming and cumbersome procedure. The methods described herein allow to combine the possibility of probing large area samples with high spatial resolution using an objective lens while illuminating the sample with a well-defined, optionally single, angle of incidence. The conventional inspection tools that have the capability of quantifying the optical properties of the periodic and quasi periodic structures are the metrology tools that have been developed and optimized for the overlay and critical dimension measurements in chip manufacturing and semiconductor industries. Therefore, the wide range of designs with different geometries, dimensions and symmetries limits the applicability of the semiconductor-based metrology machines as a versatile tool for more general purposes. Furthermore, the large volume of generated data, complexity of the machine, complicated data analysis and high price range associated with these metrology technologies creates a demand for a different machine with a small footprint, yet effective for measuring the optical response of large area patterned surfaces. In an embodiment, this disclosure provides a metrology method and instrument based on measuring the diffraction order generated by periodic or quasi periodic samples to assess the quality of the nanostructured periodic patterns. The sample is preferably illuminated with collimated light via an objective lens of a microscope in order to probe an area with the diameter of few micrometer. The same objective lens may be used to collect simultaneously the diffraction orders generated by the sample. The relative intensity of the diffraction orders can then be used for evaluating the quality of the sample, in particular whether the dimensions of the one or more structures are as intended. Due to the fact that the sample is illuminated with a collimated and well-defined angle of incidence the analysis of the diffraction orders is relatively simple and straightforward. Exemplary embodiments include microscopes and metrology instruments for inspecting/analyzing structures. Embodiments may include a processor configured to implement an inverse modeling method for determining one or more sample geometrical features (e.g., period or size of periodic features etc.) based on one or more measured diffraction orders. Another exemplary embodiment is a method of determining sample features by modeling diffraction data gathered according to principles described herein.

FIG. 3 illustrates a captured image according to an embodiment. In particular, FIG. 3 represents the measurements of a blazed 1D grating where the −1 diffraction order is seen to be more efficient that the +1 diffraction order. The three clear “dots”, i.e. the three regions, represent spatial regions in the (further) focal plane having a relatively high radiant power. In this example, the three regions are respectively associated with the +1th diffraction order, the 0th diffraction order and the −1th diffraction order as shown. Further, the top graph on the right hand side indicates the radiant power along the horizontal, dashed line 28 in the (further) focal plane and the bottom graph indicates the radiant power along the vertical, dashed line 30 in the (further) focal plane.

The table below lists different properties for the three diffraction orders shown in FIG. 3.

| Diffrac- | Peak | | | | Integrated | Ration |
|---|---|---|---|---|---|---|
| tion | intensity | Theta | Phi | Ratio | intensity | to 0^{th} |
| orders | (10⁴) | (deg) | (deg) | to 0th | (10⁷) | (integrated) |
| Diff 0 | 2.6279 | −0.41 | 2.81 | 1 | 3.033 | 1 |
| Diff 1 | 1.2857 | −0.32 | 55.74 | 0.49 | 3.509 | 0.12 |
| Diff −1 | 3.6631 | 0.32 | −52.94 | 1.39 | 2.7482 | 1.24 |

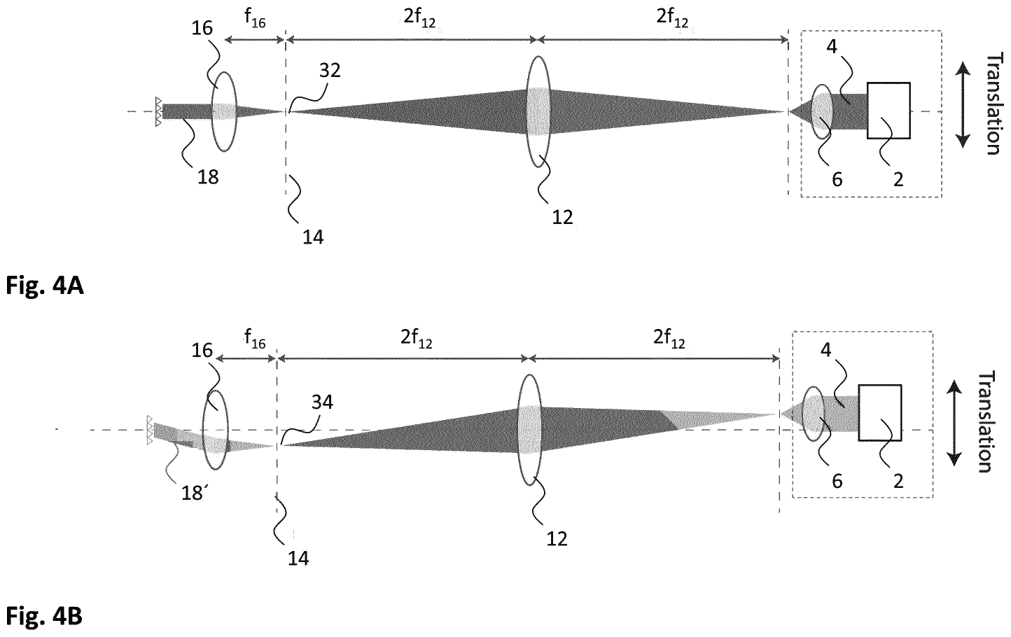

FIGS. 4A and 4B illustrate a system according to an embodiment in two respective states. In the first state (top), the illumination light 4 is focused at point 32 in the focal plane 14 of lens system 16. The point 32 has a certain position relative to the lens system 16. In the FIG. 4A, the position 32 is such that the collimated illumination light beam 18 is incident on the sample surface having an orientation that is perpendicular to the sample surface.

In FIG. 4B, the illumination light 4 is focused on another point 34 in focal plane 14 of lens system 16. As a result, a second collimated illumination light beam 18′ is formed. This light beam has a different orientation relative to the sample surface than light beam 18 in FIG. 4A. Hence, by moving the focal point of the illumination light in focal plane 34, the orientation of the collimated illumination light beam can be varied. This provides a convenient manner for scanning the illumination with light having different orientations.

As explained above, an image is captured for each orientation of the collimated illumination light beam. The one or more dimensions of the one or more structures can then be determined based on these images.

In particular, FIG. 4 illustrates that the point in focal plane 14 where illumination light 4 is focused can be varied by moving the illumination light source 2 relative to the lens system 16.

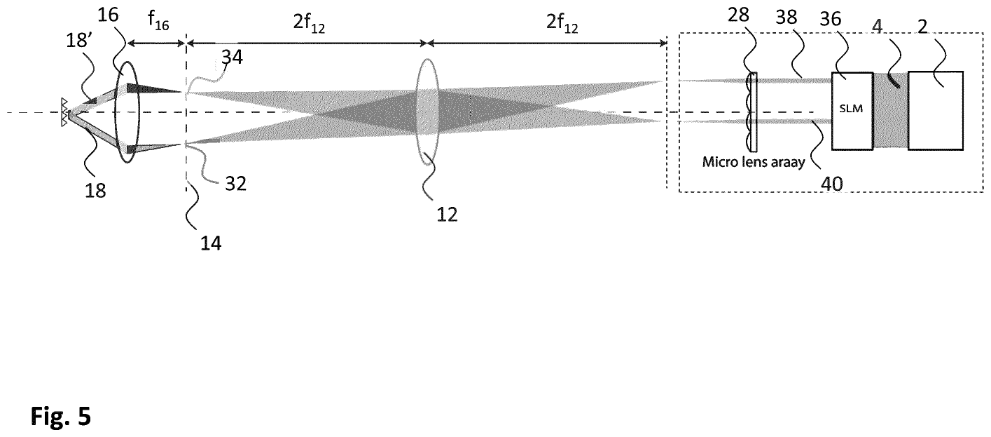

FIG. 5 illustrates an embodiment of the system that can vary the position where the illumination light 4 is focused in the focal plane 14 using a spatial light modulator. By illuminating the SLM with e.g. a laser, one can produce arbitrary illumination profiles. Hence, one can illuminate every single lens in the micro-lens array 28 separately. This will result in the possibility of focusing the light at different positions on back-focal plane 14 of the objective 16, resulting in the collimated light with oblique angle without the need of any mechanical motion of the illumination light source 2.

First a spatial light modulator 36 may be controlled to allow a first spatial portion 37 of illumination light 4 incident on the spatial light modulator 36 to pass through and travel to the sample surface. As a result, the illumination light may be focused on point 32 in the focal plane 14, giving rise to collimated illumination light beam 18. At the same time, the spatial light modulator may be controlled to allow a second spatial portion 40 of illumination light 4 incident on the spatial light modulator 36 to pass through and travel to the sample surface. As a result, the illumination light is focused on point 34 in the focal plane 14 giving rise to collimated illumination light beam 18′.

FIG. 5 illustrates that two collimated light beams 18 and 18′ may be incident on the sample surface simultaneously. The two beams can be also incident on the sample one after another.

The embodiment of FIG. 5 utilizes a combination of spatial light modulator (SLM) and a micro lens array 28. By illuminating the SLM with a laser, one can produce arbitrary illumination profiles. Hence, one can illuminate every single lens in the array 28 separately. This will results in the possibility of focusing the light at different positions on back-focal plane of the objective, resulting in the collimated light with oblique angle without the need of mechanically moving the sample with respect to the light source.

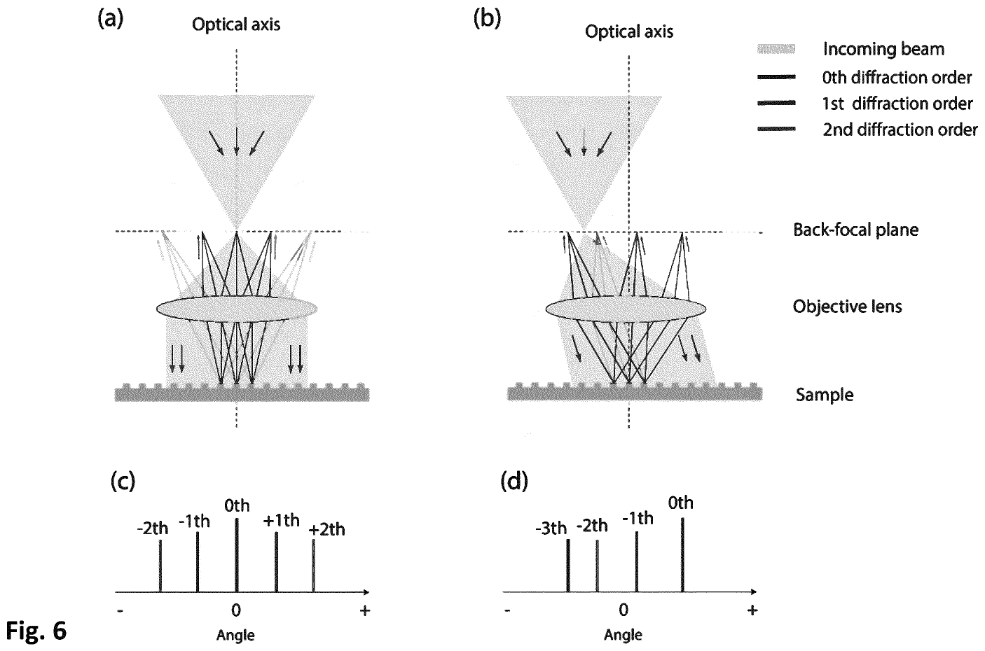

FIG. 6 illustrates that in order to collect the orders that do not fit within the acceptance angle of the lens, the excitation can be displaced horizontally with respect to the optical axis. This displacement may be realized by placing the light source (such as laser) on a translation stage. Additionally or alternatively, the displacement is realized using a spatial light modulator as described herein. This displacement provides an extra wavevector for the illuminating beam that leads to the oblique incidence angle. Therefore, the orders of diffraction will be shifted spatially and in proportion to the wavevector of the illumination beam. This principle can bring the diffraction orders that initially (under normal incidence) were out of the collection range into the collection range of the objective lens.

After illumination of the sample with the collimated light, diffraction order such that their angle with respect to the optical axis fall within the numerical aperture of the objective lens 16 will be collected by the objective lens 16. These diffraction orders are focused on the back-focal plane of the objective lens 16. These orders can be imaged on a CCD camera 22 using an intermediate 12. In order to collect the diffraction orders that do not fit within the acceptance angle of the objective lens 12, the excitation can be displaced horizontally with respect to the optical axis. This displacement can be realized by placing the illumination unit (such as laser) on a translation stage (see FIG. 4). This displacement provides an extra wavevector for the illuminating beam that leads to an oblique incidence angle. Therefore, the orders of diffraction will be shifted spatially and in proportion to the wavevector of the illumination beam. This principle can bring the diffraction orders that initially (under normal incidence) were out of the collection range into the collection range of the objective lens.

FIG. 6A illustrates normal incidence and FIG. 6C illustrates the orders of diffraction obtained by the microscope for normal incidence. FIG. 6B illustrates oblique incidence and FIG. 6D illustrate the orders of diffraction obtained by the microscope for the oblique incidence.

The method and system disclosed herein enable to measure several diffraction orders simultaneously for a given orientation of the collimated illumination light beam, e.g. for a given angle of incidence. By combining simultaneous detection of the diffraction orders with the possibility of scanning the incidence angle, one can map out the radiant power, also referred to as the intensity, of the detected diffraction orders as a function of the incidence angle. This measurement mode provides a valuable dataset that can be used to characterize geometrical properties of the sample surface such as their pitch size, particle size and residual layer thickness. In addition, one can use this method for the in-depth quality inspection of the periodic structures with a high spatial resolution (50-100 micrometer).

Conventional approach for measuring intensities of diffraction orders as a function of different angles of incidence requires two scanning stage. With one scanning stage, the operator sets the angle of incidence while the other scanning stage measures diffracted orders by scanning the detector over different possible angles. Three main disadvantage of these system are as following:

1—Long measurement times to measure the intensity of diffracted orders as a function of the incident angle.

2—Limited detection angles

3—Detection of the diffracted orders is limited to orders that are in the plane of the incident. Therefore, out-of-plane diffraction orders (for two-dimensional gratings) cannot be detected.

With the technology disclosed herein, due to the fact that the diffraction orders are imaged by the imaging system, the use of scanning detection arm is obviated. This feature allows us to collect diffracted orders over a much wider range in less than a second. In fact, the only limiting factor for collecting the diffraction orders (at a given angle of incidence) is just the numerical aperture of the objective lens.

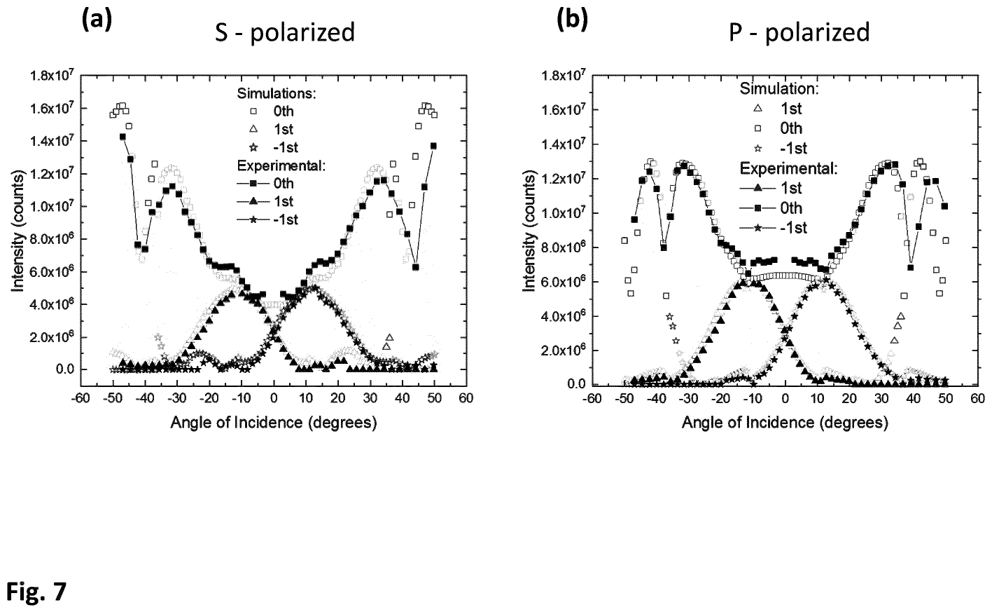

An example of such measurements is shown in FIGS. 7A and 7B. For these figures, the diffraction efficiency of the 0th, 1st and −1st orders as a function of the angle of incidence for two different polarizations have been measured. The investigated sample surface in this figure is a 1D grating with the pitch size of 1000 nm, residual layer thickness of 495 nm and height of 175 nm on a silicon substrate.

FIGS. 7A and 7B show respective radiant powers, as represented by captured images of a (further) focal plane described herein, for different diffraction orders, for different angles of incidence for the collimated illumination light beam, for different polarizations of the illumination light. FIG. 7A shows the radiant powers for illumination light having an s-polarization and FIG. 7B the respective radiant power for illumination light having a p-polarization. Further, as indicated, the black squares indicate the respective radiant powers for the 0^{th} diffraction orders, the grey squares for the 1^{st} diffraction order, the grey solid circles for the −1^{st} diffraction order.

In the graphs of FIGS. 7A and 7B the measured values of radiant powers for a single angle of incidence are typically derived from a single captured image that comprises different regions, each region comprising pixels representing a radiant power of a respective diffraction order. FIG. 3 shows an example of such a captured image.

Graphs 7A and 7B also simulated radiant powers for the corresponding diffraction orders, for corresponding angles of incidence for the collimated illumination light beam, for corresponding polarizations of the illumination light. The simulated radiant powers may also be referred to as a set of reference images, wherein each reference image is associated with an orientation of the collimated illumination light beam or with a polarization of the illumination light. In the particular case of FIG. 7, each reference image may be understood to be associated with a respective combination of (i) orientation of the collimated illumination light beam and (ii) polarization of the illumination light. Thus, for example, the simulated values for the respective diffraction orders −1, 0 and +1, associated with both s-polarization (thus shown in FIG. 7A) and with 35 degrees angle of incidence may be understood to form one reference image. The simulated values for the respective diffraction orders −1, 0 and +1, associated with both s-polarization (thus shown in FIG. 7A) and with 50 degrees angle of incidence may be understood to form another reference image. Each reference images thus indicates a reference distribution of radiant of light in the (further) focal plane in that the distribution of radiant power across several diffraction orders are indicated. The simulated radiant powers shown in graphs 7A and 7B may be understood to form a single set of reference images, which single set is associated with a single reference sample surface.

Graph 7A and 7B thus illustrate a comparison between captured images and a set of reference images. In this example, the reference images and the captured images are similar. Hence, based on this, it can be determined that the actual sample surface that was investigated is similar to the reference sample surface that was used to determine the simulated values shown in FIGS. 7A and 7B. Hence, the one or more dimensions of structures on the investigated sample surface are equally dimensioned as the (virtual) structures on the (virtual) reference sample.

The features that are visible in FIGS. 7A and 7B are unique and very much dependent on the characteristic design and geometry of the investigated sample. Any variation in the geometry of the grating such as height variations or the change of residual layer thickness lead to the modification of these patterns. Hence, comparison between these measurements and simulations provides quantitative information about the geometry of the measured sample.

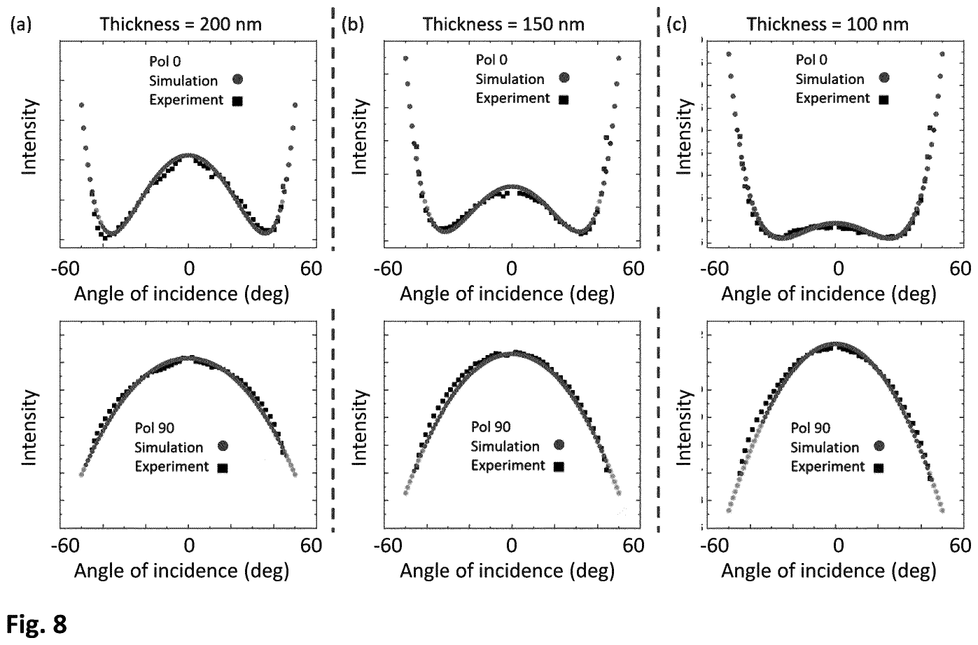

The systems and methods disclosed herein also enable to precisely measure the layer thickness of thin films by just scanning the incidence angle on the thin films and measuring the radiant power, also referred to as intensity, of the reflected light. In FIG. 8, one can see how the intensity of the reflected light (for different polarizations) changes as a function of the layer thickness. By comparing these measurements with the simulations, it is possible to determine the layer thickness with a great accuracy. The refractive index of the samples at the frequency of the incident laser may be input for the simulations.

One of the possible upgrade on this instrument is to combine the CCD camera with polarimetry equipment to quantify the modification of the polarization of the incident beam due to the sample structures. The comparison between the polarization of the incident and detected light provides sensitive information about the structure of the sample, in particular allows to determine dimensions of one or more structures on the sample surface.

This instrument combined with polarimetry allows one to set a polarized illumination with a well-defined angle of incidence on a sample and probe the associated changes of the polarization on the sample.

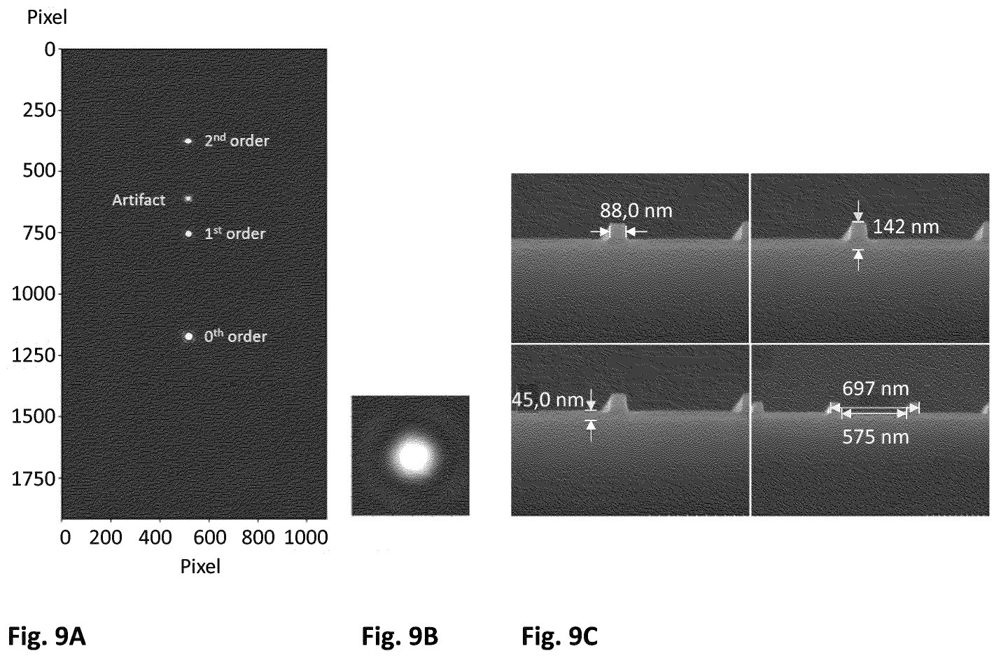

Once the sample is illuminated under a well-defined angle of incidence, it generates a series of measurements for every angle of incidence that needs to be processed. FIG. 9 shows an example of such a measurement (raw data). In this case, a 1D grating was present on the sample surface with 700 nm pitch size as shown in FIG. 9C.

FIG. 9A is a captured image of the (further) focal plane according to an embodiment. Here the sample is illuminated under −20 degree. As shown, this captured image comprises three regions, each region comprising a plurality of pixels representing a radiant power of a respective diffraction order. However, in this captured image an artifact region is also present which should not be mistaken for a region associated with a diffraction order. This artifact originates from the back reflection of the laser from existing optics in the optical path. The problem with these type of artifacts is that under certain angles they can interfere with incoming diffraction orders and introduce noise. The problem with the noise is something that we have addressed by proper referencing of the data explained below.

Each region associated with a diffraction order comprises pixels that indicate a radiant power. Each pixel may indicate a respective radiant power. It should be appreciated that determining a radiant power associated with such a plurality of pixels in a region, for example a region as depicted in FIG. 9B, may comprise summing the respective radiant powers as indicated by the respective pixels in that image region.

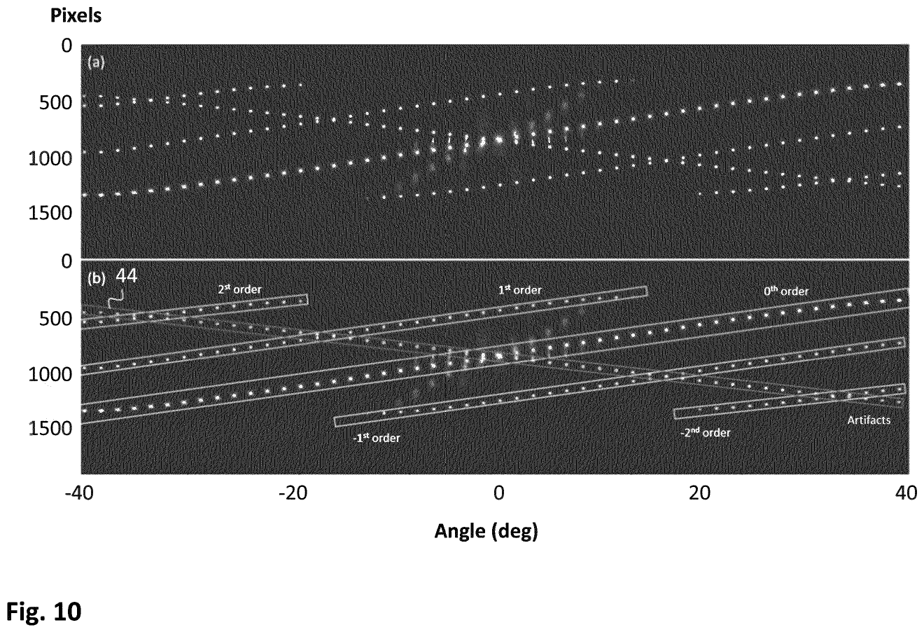

A first step in the data processing is to plot all measured radiant powers as a function of the angles of incidence that are used in the measurements. FIG. 10 shows all the measured orders in addition to the existing artifacts for every angle of incidence (from −40 until 40 degree with steps of 1.6 deg). The sample under the investigation is a 1D grating with 700 nm pitch size. This map is created by stacking all the measurements next to each other. The map could be also generated by simultaneously illuminating the sample with a collection of beams each at an angle of incidence. It can be seen that in addition to the artifact that runs over the entire measurement (indicated by rectangle 44), as normal incidence is approached (angle close to 0 deg), some diffuse background signals start to appear as well. These are a second type of artifacts that are formed due to the reflection of the light from the optics back into the camera.

To reduce the influence of artifacts and noise that is introduced into the measurements due to the interference of these reflections with the main diffraction signals, the captured images may be processed as follows.

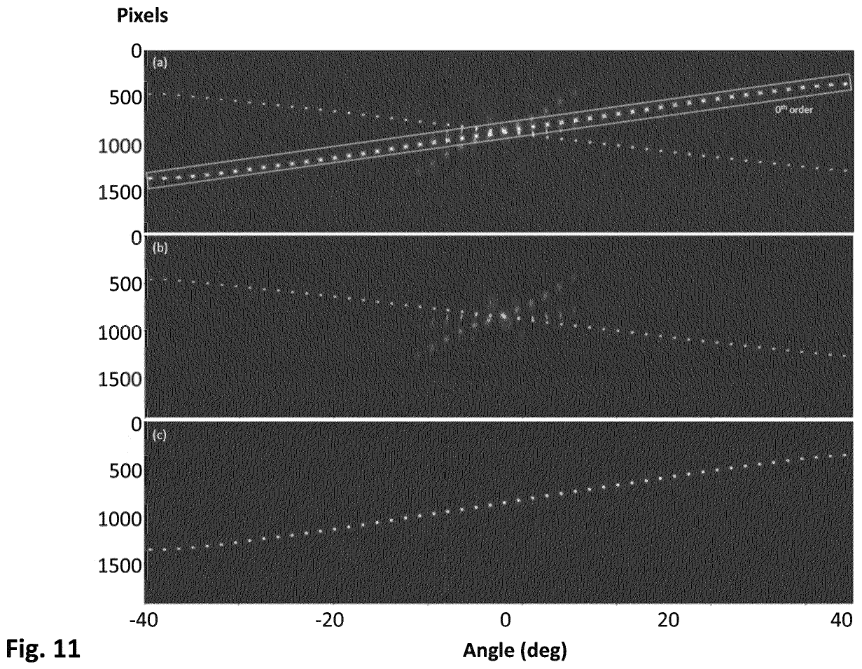

FIG. 11A shows the raw data, i.e. the captured images, from just a clean silicon wafer. Silicon wafer can only reflect the light in the opposite direction (0th order) and it cannot support any diffraction orders. Any other signal except what is indicated as “0th order” in FIG. 11A is an artifact that needs to be removed. Due to the fact that these artifacts are originated from the reflection of the optics along the optical path of the microscope, they can be removed by proper referencing. It is possible to run one measurement without any sample under the microscope in order to record only these artifacts (Blank measurement) (see FIG. 11B). Afterward, by subtracting the blank measurement from the original raw data from the sample (in this case silicon), we will end up with a clean data set with minimum influence from the back-reflections into the camera and artifacts (see FIG. 11C).

Another step in analyzing the data is to normalize them by a proper reference. Normalizing by the reference removes the need of any further calibration in the system. These calibrations involve intensity of the diffracted light or any influence that aberrations in the optics can have on the results. The above described measurements on a silicon wafer may be used as a reference. Initially for every angle of incidence, the intensity of the diffraction for a certain order can be integrated over the pixel range, i.e. region, that the peak is measured. This approach efficiently removes most of the possible artifacts that are incorporated into the signal and/or any other irregularities that can be induced into the signal due to misalignment.

Afterward, the measurements on every samples is normalized by the measurements on the silicon wafer according to the following relation:

$$Normalized Intensity = \frac{{I}_{sample} - {I}_{Blank}}{{I}_{S i l i c o n} - {I}_{Blank}}$$

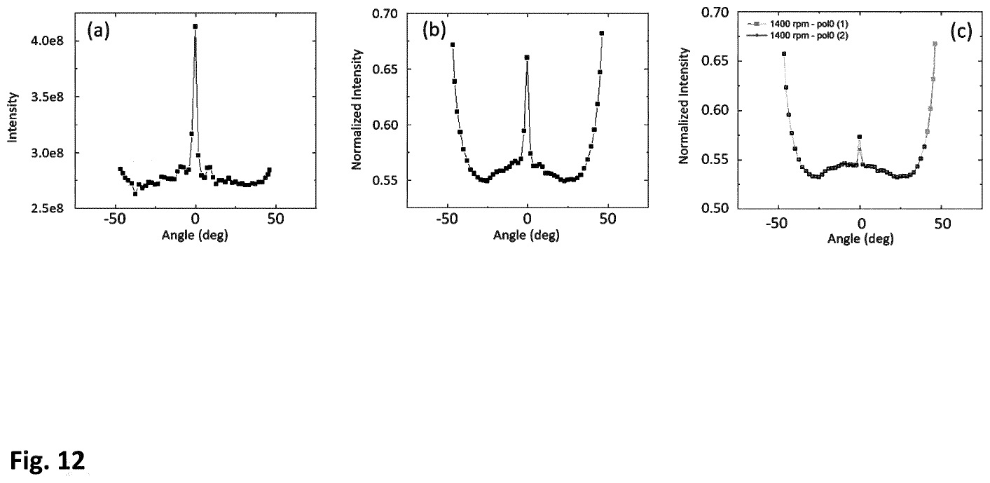

FIG. 12 illustrates the effect of the artifact removal and normalization on the measurements obtained from a thin layer of polymer with 90 nm thickness and refractive index of 1.45.

FIG. 12A shows raw data, captured images, without any correction/normalization. FIG. 12B shows measurements normalized by silicon without subtracting the above described blank measurements. FIG. 12C shows measurements normalized by silicon and subtraction of the blank measurement. In panel (c) red and black data are two independent measurements (for the purpose of reproducibility).

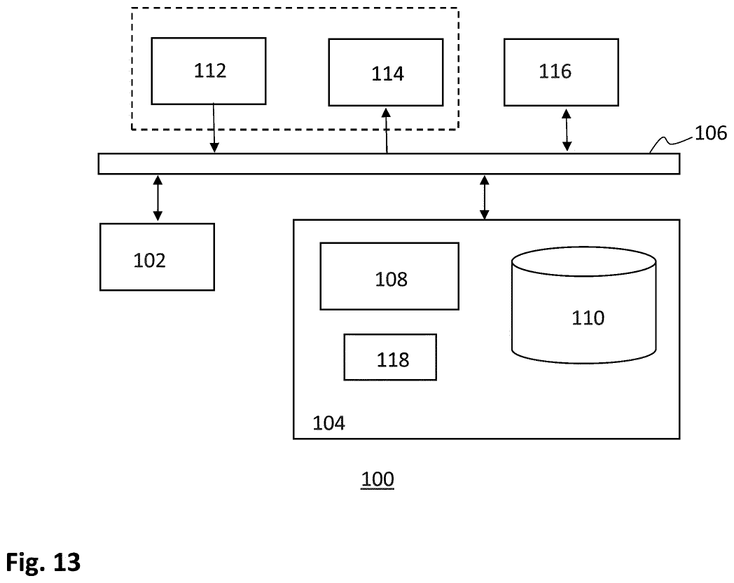

FIG. 13 depicts a block diagram illustrating a data processing system according to an embodiment.

As shown in FIG. 13, the data processing system 100 may include at least one processor 102 coupled to memory elements 104 through a system bus 106. As such, the data processing system may store program code within memory elements 104. Further, the processor 102 may execute the program code accessed from the memory elements 104 via a system bus 106. In one aspect, the data processing system may be implemented as a computer that is suitable for storing and/or executing program code. It should be appreciated, however, that the data processing system 100 may be implemented in the form of any system including a processor and a memory that is capable of performing the functions described within this specification.

The memory elements 104 may include one or more physical memory devices such as, for example, local memory 108 and one or more bulk storage devices 110. The local memory may refer to random access memory or other non-persistent memory device(s) generally used during actual execution of the program code. A bulk storage device may be implemented as a hard drive or other persistent data storage device. The processing system 100 may also include one or more cache memories (not shown) that provide temporary storage of at least some program code in order to reduce the number of times program code must be retrieved from the bulk storage device 110 during execution.

Input/output (I/O) devices depicted as an input device 112 and an output device 114 optionally can be coupled to the data processing system. Examples of input devices may include, but are not limited to, a keyboard, a pointing device such as a mouse, a touch-sensitive display, or the like. Examples of output devices may include, but are not limited to, a monitor or a display, speakers, or the like. Input and/or output devices may be coupled to the data processing system either directly or through intervening I/O controllers.

In an embodiment, the input and the output devices may be implemented as a combined input/output device (illustrated in FIG. 13 with a dashed line surrounding the input device 112 and the output device 114). An example of such a combined device is a touch sensitive display, also sometimes referred to as a “touch screen display” or simply “touch screen”. In such an embodiment, input to the device may be provided by a movement of a physical object, such as e.g. a stylus or a finger of a user, on or near the touch screen display.

A network adapter 116 may also be coupled to the data processing system to enable it to become coupled to other systems, computer systems, remote network devices, and/or remote storage devices through intervening private or public networks. The network adapter may comprise a data receiver for receiving data that is transmitted by said systems, devices and/or networks to the data processing system 100, and a data transmitter for transmitting data from the data processing system 100 to said systems, devices and/or networks. Modems, cable modems, and Ethernet cards are examples of different types of network adapter that may be used with the data processing system 100.

As pictured in FIG. 13, the memory elements 104 may store an application 118. In various embodiments, the application 118 may be stored in the local memory 108, the one or more bulk storage devices 110, or apart from the local memory and the bulk storage devices. It should be appreciated that the data processing system 100 may further execute an operating system (not shown in FIG. 13) that can facilitate execution of the application 118. The application 118, being implemented in the form of executable program code, can be executed by the data processing system 100, e.g., by the processor 102. Responsive to executing the application, the data processing system 100 may be configured to perform one or more operations or method steps described herein.

Various embodiments of the invention may be implemented as a program product for use with a computer system, where the program(s) of the program product define functions of the embodiments (including the methods described herein). In one embodiment, the program(s) can be contained on a variety of non-transitory computer-readable storage media, where, as used herein, the expression “non-transitory computer readable storage media” comprises all computer-readable media, with the sole exception being a transitory, propagating signal. In another embodiment, the program(s) can be contained on a variety of transitory computer-readable storage media. Illustrative computer-readable storage media include, but are not limited to: (i) non-writable storage media (e.g., read-only memory devices within a computer such as CD-ROM disks readable by a CD-ROM drive, ROM chips or any type of solid-state non-volatile semiconductor memory) on which information is permanently stored; and (ii) writable storage media (e.g., flash memory, floppy disks within a diskette drive or hard-disk drive or any type of solid-state random-access semiconductor memory) on which alterable information is stored. The computer program may be run on the processor 102 described herein.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of embodiments of the present invention has been presented for purposes of illustration, but is not intended to be exhaustive or limited to the implementations in the form disclosed. Many modifications and variations will be apparent to those of ordinary skill in the art without departing from the scope and spirit of the present invention. The embodiments were chosen and described in order to best explain the principles and some practical applications of the present invention, and to enable others of ordinary skill in the art to understand the present invention for various embodiments with various modifications as are suited to the particular use contemplated.

1. A method for determining one or more dimensions of one or more structures on a sample surface, the method comprising
focusing illumination light on a focal plane of a lens system so that the lens system forms a collimated illumination light beam that is incident on the sample surface and that is reflected from or transmitted through the sample surface, and
using said lens system or a further lens system to collect illumination light reflected from or transmitted through the sample surface, and
capturing an image of said focal plane of said lens system or of a further focal plane of said further lens system to provide a captured image, said captured image representing a distribution, in said focal plane or said further focal plane, of radiant power of the reflected or transmitted illumination light, and
based on the captured image, determining the one or more dimensions of the one or more structures on the sample surface.

2. The method according to claim 1, wherein a cross section of the collimated illumination light beam has a surface area of at least 5 micrometers.

3. The method according to claim 1, further comprising
storing one or more reference images, each of the one or more reference images being associated with a reference sample surface comprising one or more structures having known dimensions, and each said reference image representing a reference distribution of radiant power of light in said focal plane or said further focal plane, wherein
determining the one or more dimensions of the one or more structures on the sample surface comprises comparing the captured image with the one or more reference images.

4. The method according to claim 3, wherein each of the one or more reference images has been obtained by performing a simulation of a collimated illumination light beam incident on the reference sample surface associated with the one or more reference images.

5. The method according to claim 1, wherein the step of focusing illumination light on the focal plane of the lens system comprises
focusing illumination light on the focal plane of the lens system so that the lens system forms a first said collimated illumination light beam that is incident on the sample surface and that is reflected from or transmitted through the sample surface and focusing illumination light on the focal plane of the lens system so that the lens system forms a second said collimated illumination light beam that is incident on the sample surface and that is reflected from or transmitted through the sample surface.

6. The method according to claim 5, wherein the first collimated illumination light beam and the second collimated illumination light beam are incident on the sample surface simultaneously.

7. The method according to claim 5, wherein the first collimated illumination light beam and second collimated illumination light beam are incident on the sample surface one after another.

8. The method according to claim 5, wherein
the step of focusing the illumination light on the focal plane of the lens system comprises focusing the illumination light at a first point in the focal plane, the first point having a first position relative to the lens system, so that the lens system forms the first collimated illumination light beam that is incident on the sample surface while having a first orientation relative to the sample surface, the method comprising
focusing the illumination light at a second point in the focal plane, the second point having a second position relative to the lens system different from the first position, so that the lens system forms the second collimated illumination light beam that is incident on the sample surface while having a second orientation relative to the sample surface that is different from the first orientation.

9. The method according to claim 8, wherein a first said illumination light is focused at the first point in said focal plane and then at the second point in the focal plane, wherein focusing the first said illumination light at the first point and then at the second point comprises moving an illumination light source relative to said lens system.

10. The method according to claim 8, wherein the step of focusing the first said illumination light at the first point and at the second point comprises
controlling a spatial light modulator to allow a first spatial portion of illumination light incident on the spatial light modulator to pass through and travel to the sample surface, and
controlling the spatial light modulator to allow a second spatial portion of illumination light incident on the spatial light modulator to pass through and travel to the sample surface.

11. The method according to claim 5, the method further comprising
controlling polarization of the illumination light such that the first collimated illumination light beam has a first polarization and the second collimated illumination light beam has a second polarization that is different from the first polarization.

12. The method according to claim 5, wherein the first collimated illumination light beam comprises a first spectral power distribution and the second collimated illumination light beam comprises a second spectral power distribution different from the first spectral power distribution.

13. The method according to claim 1, wherein capturing an image of said focal plane or of the further focal plane of the further lens system comprises
using said lens system or the further lens system, collecting first reflected or transmitted illumination light that is light from the first collimated illumination light beam reflected from or transmitted through the sample surface, and
capturing a first said image of said focal plane or of said further focal plane, said first image representing a distribution in said focal plane or further focal plane of radiant power of the first reflected or transmitted illumination light, and
using said lens system or the further lens system, collecting second reflected or transmitted illumination light that is light from the second collimated illumination light beam reflected from or transmitted through the sample surface, and
capturing a second said image of said focal plane or of said further focal plane, said second image representing a distribution in said focal plane or further focal plane of radiant power of the second reflected or transmitted illumination light, and
based on the first image and second image, determining the one or more dimensions of the one or more structures on the sample surface.

14. The method according to claim 13, comprising
storing one or more sets of reference images, each set comprising a first reference image associated with said first orientation and/or first polarization and/or first spectral power distribution of the illumination light beam and a second reference image associated with said second orientation and/or second polarization and/or second spectral power distribution of the illumination light beam, and each set of reference images being associated with a respective reference sample surface comprising one or more structures having known dimensions, wherein
determining the one or more dimensions of the one or more structures on the sample surface comprises comparing the first image with the first reference image in each of the one or more sets of the reference images and comparing the second image with the second reference image in each of the one or more sets of the reference images.

15. The method according to claim 1, further comprising
determining a region in the captured image comprising a plurality of pixels representing a radiant power in said focal plane or the further focal plane of the reflected or transmitted illumination light associated with a diffraction order, and
determining the radiant power associated with said diffraction order based on said plurality of pixels in the region, and
determining the one or more dimensions of the one or more structures on the sample surface based on the determined radiant power associated with the diffraction order.

16. The method according to claim 15, further comprising
determining a first region in the captured image comprising a plurality of pixels representing a first radiant power in said focal plane or the further focal plane of the reflected or transmitted illumination light associated with a first diffraction order, and
determining the first radiant power associated with said first diffraction order based on said plurality of pixels in the first region, and
determining a second region in the captured image comprising a plurality of pixels representing a second radiant power in said focal plane or the further focal plane of the reflected or transmitted illumination light associated with a further diffraction order, and
determining the second radiant power associated with the further diffraction order based on the plurality of pixels in the second region, and
determining the one or more dimensions of the one or more structures on the sample surface based on the determined first radiant power associated with the first diffraction order and the determined second radiant power associated with the further diffraction order.

17. The method according to claim 14, further comprising
determining a first region in the first captured image comprising a plurality of pixels representing a first radiant power in said focal plane or the further focal plane of the reflected or transmitted illumination light associated with a first diffraction order, and
determining the first radiant power associated with said first diffraction order based on said plurality of pixels in the first region, and
determining a second region in the first captured image comprising a plurality of pixels representing a second radiant power in said focal plane or the further focal plane of the reflected or transmitted illumination light associated with a further diffraction order, and
determining the second radiant power associated with the further diffraction order based on the plurality of pixels in the second region, and
determining a first region in the second captured image comprising a plurality of pixels representing a third radiant power in said focal plane or the further focal plane of second reflected or transmitted illumination light associated with the first diffraction order, and
determining a second region in the second captured image comprising a plurality of pixels representing a fourth radiant power in said focal plane or the further focal plane of the second reflected or transmitted illumination light associated with the further diffraction order, and
determining said third radiant power based on said plurality of pixels of the first region in the second captured image, and
determining the fourth radiant power based on said second plurality of pixels in the second region of the second captured image, and wherein
the first reference image indicates a first reference radiant power for said diffraction order and a second reference radiant power for said further diffraction order, and wherein the second reference image indicates a third reference radiant power for said first diffraction order and a fourth reference radiant power for said further diffraction order, wherein
determining the one or more dimensions of the one or more structures on the sample surface comprises comparing said first radiant power with the first reference radiant power and the second radiant power with the second reference radiant power and the third radiant power with the third reference radiant power and the fourth radiant power with the fourth reference radiant power.

18. The method according to claim 1, comprising scanning the collimated illumination light over the sample surface.

19. A system for determining one or more dimensions of one or more structures on a sample surface, the system comprising
a lens system, and
a light focusing system that is configured to focus illumination light on a focal plane of the lens system so that the lens system forms a collimated illumination light beam that is incident on the sample surface, wherein
the lens system is configured to collect illumination light reflected from the sample surface or wherein the system comprises a further lens system that is configured to collect illumination light transmitted through the sample surface, and
an imaging system that is configured to capture an image of said focal plane or of a further focal plane of said further lens system, said image representing a distribution in said focal plane or the further focal plane of radiant power of the reflected or transmitted illumination light, and
a data processing system that is configured to, based on the captured image, determine the one or more dimensions of the one or more structures on the sample surface.

20. A computer-implemented method for determining one or more dimensions of one or more structures on a sample surface, the method comprising
obtaining an image, the image representing a distribution in a focal plane for a further focal plane of radiant power of reflected or transmitted illumination light, the image being obtainable by focusing illumination light on said focal plane of a lens system so that the lens system forms a collimated illumination light beam that is incident on the sample surface and, using said lens system, collecting illumination light reflected from or, using a further lens system, collecting illumination light transmitted through the sample surface, and capturing the image of the focal plane or the further focal plane, the method further comprising
storing one or more reference images, each of the one or more reference images being associated with a reference sample surface comprising one or more structures having known dimensions, and each reference image representing a reference distribution of radiant power of light in said focal plane or the further focal plane, wherein
determining the one or more dimensions of the one or more structures on the sample surface comprises comparing the captured image with the one or more reference images.

21. A data processing system comprising a processor that is configured to perform the method according to claim 20.

22. A computer program comprising instructions which, when the program is executed by a data processing system, cause the data processing system to carry out the method of claim 20.
